(19) United States
(12) Patent Application Publication
(10) Pub. No.: US 2023/0290763 A1
(43) Pub. Date: Sep. 14, 2023

(54) HYBRID CONTROL FOR LEDS, PIXELS, AND DISPLAYS

(71) Applicant: X Display Company Technology Limited, Dublin (IE)

(72) Inventors: Matthew Alexander Meitl, Durham, NC (US); Christopher Andrew Bower, Raleigh, NC (US); Ronald S. Cok, Rochester, NY (US); Murat Ozbas, Penfield, NY (US)

(21) Appl. No.: 17/848,311

(22) Filed: Jun. 23, 2022

Related U.S. Application Data
(60) Provisional application No. 63/320,585, filed on Mar. 16, 2022.
(60) Provisional application No. 63/319,239, filed on Mar. 11, 2022.

(51) Int. Cl. H01L 25/16; H01L 25/04; H01L 25/075; H01L 27/12

(52) U.S. Cl. CPC H01L 25/167; H01L 25/048; H01L 25/0753; H01L 27/1225; H01L 27/1255; H01L 29/78663

(57) ABSTRACT

A hybrid-control pixel includes a TFT substrate, a TFT circuit formed on the TFT substrate, a micro-device having an integrated-circuit substrate separate and independent from the TFT substrate disposed on or over the TFT substrate, a micro-circuit electrically connected to the TFT circuit, and an LED or other device disposed on the integrated circuit or the TFT substrate. The LED can be electrically connected to the micro-circuit and the TFT circuit and the micro-circuit together control the LED.

### PRIORITY APPLICATIONS

This application claims the benefit of U.S. Provisional Patent Application No. 63/319,239, filed Mar. 11, 2022, entitled Hybrid Control for Pixels and Displays, and U.S. Provisional Patent Application No. 63/320,585, filed Mar. 16, 2022, entitled Thin-Film-Transistor (TFT) Display Backplanes with Micro-Integrated Circuits (MICRO-IC), the disclosures of each of which is hereby incorporated by reference herein in its entirety.

### CROSS REFERENCE TO RELATED APPLICATIONS

Reference is made to commonly assigned U.S. Pat. No. 10,230,048, entitled OLEDs for Micro-Transfer Printing, by Bower et al filed Sep. 29, 2015, the disclosure of which is incorporated herein by reference in its entirety.

### TECHNICAL FIELD

The present disclosure relates generally to micro-assembled integrated-circuit micro-devices and thin-film circuits for controlling devices and components.

### BACKGROUND

Flat-panel displays are widely used in conjunction with computing devices, in portable devices, and for entertainment devices such as televisions. Such displays typically employ a plurality of pixels distributed over a display substrate to display images, graphics, or text. In a color display, each pixel includes light emitters that emit light of different colors, such as red, green, and blue. For example, liquid crystal displays (LCDs) employ liquid crystals to block or transmit light from a backlight behind the liquid crystals and organic light-emitting diode (OLED) displays rely on passing current through a layer of organic material that glows in response to the current. Displays using inorganic light emitting diodes (LEDs) are also in widespread use for outdoor signage and have been demonstrated in a 55-inch television.

The various light-emitting technologies have different characteristics, advantages, and disadvantages. For example, liquid crystals are simple to control and have a highly developed and sophisticated technological infrastructure. Organic LEDs are area emitters, can be more efficient and flexible, have an excellent viewing angle, and are demonstrated in a very thin form factor. Inorganic light-emitting diodes are very efficient and provide relatively saturated light in an environmentally robust structure. Lasers are also efficient and provide a virtually monochromatic light but have a limited viewing angle. None of these technologies, however, meet all of a display viewer's needs under all circumstances.

Organic light-emitting diodes are widely used in portable electronic devices with displays and in some televisions. The OLEDs are usually coated on a display substrate together with a thin-film-transistor (TFT) circuit that controls the OLEDs. The light emitted from OLEDs directly corresponds to the current passing through the OLED. However, light-output control signals in displays with TFT circuits are typically voltage signals, so that a voltage-to-current conversion circuit is generally necessary to efficiently and accurately control an OLED in a display. Such TFT circuits can be large and complex and take up a relatively large area on a display substrate. Nonetheless, TFT circuits are widely used in OLED and LCD displays and manufacturing processes for such TFT circuits are well developed and industrially available. TFT circuits can comprise one or more of: amorphous silicon (aSi), low-temperature polycrystalline silicon (LTPS), high-temperature polycrystalline silicon (HTPS), indium gallium zinc oxide (IGZO), and low-temperature polycrystalline oxide (LTPO).

Substrates with electronically active components distributed over the extent of the substrate are used in a variety of electronic systems, including displays. Individually packaged integrated-circuit devices typically have smaller transistors with higher performance than thin-film-transistors but the packages are larger than can be desired for highly integrated systems such as displays. Methods for transferring active components from one substrate to another are described in U.S. Pat. No. 7,943,491. In an example of these approaches, small integrated circuits are formed on a native semiconductor source wafer. The small unpackaged integrated circuits, or chiplets, are released from the native source wafer by etching a layer formed beneath the circuits. A viscoelastic stamp is pressed against the native source wafer and the process side of the chiplets is adhered to individual stamp posts. The chiplets on the stamp are then pressed against a destination substrate or backplane with the stamp and adhered to the destination substrate. In another example, U.S. Pat. No. 8,722,458 entitled Optical Systems Fabricated by Printing-Based Assembly teaches transferring light-emitting, light-sensing, or light-collecting semiconductor elements from a wafer substrate to a destination substrate or backplane.

Small, micro-assembled systems have a desirably small footprint, are efficient, and inexpensive. There is a need, therefore, for structures and methods for micro-assembling components comprising different materials into useful systems with a small area.

### SUMMARY

The present disclosure provides, inter alia, structures, materials, and methods for micro-assembling micro-components and micro-devices into a micro-device structure or micro-system. The micro-device structure can provide a more densely packed and smaller micro-assembled system useful for efficiently controlling devices such as inorganic light-emitting diodes or organic light-emitting diodes, for example in a display.

According to embodiments of the present disclosure, a hybrid-control pixel comprises a thin-film substrate (a TFT substrate), a thin-film transistor (TFT) circuit formed on or in the TFT substrate, a micro-device comprising an integrated-circuit substrate separate and independent from the TFT substrate disposed on or over the TFT substrate, a micro-circuit electrically connected to the TFT circuit, and a light-emitting diode (LED) disposed on the integrated circuit or the TFT substrate. The LED can be electrically connected to the micro-circuit and the TFT circuit and the micro-circuit can be operable to control the LED. The micro-device and the LED can be mounted on a common pixel substrate non-native to (e.g., separate, individual, and different from) the thin-film substrate that is disposed on the thin-film substrate.

In some embodiments, the hybrid-control pixel comprises three different LEDs disposed on the micro-device. The three different LEDs can comprise a red LED operable to emit red light, a green LED operable to emit green light, and a blue LED operable to emit blue light.

The LED can be an organic light-emitting diode (OLED). The OLED can be native to (e.g., coated on) the micro-device or can be native to (e.g., formed in or on) the TFT substrate. In some embodiments, the OLED can be non-native to the micro-device, can comprise an OLED structure (e.g., substrate) separate and independent from the micro-device, and is disposed on the micro-device. In some embodiments, the OLED is non-native to the TFT substrate, comprises an OLED structure (e.g., substrate) separate and independent from the TFT substrate, and is disposed on the TFT substrate.

In some embodiments, the LED is an inorganic light-emitting diode (iLED). The iLED can be non-native to the micro-device, can comprise an iLED substrate separate and independent from the micro-device, and can be disposed on the micro-device.

In some embodiments, the LED comprises connection posts electrically connected to the micro-circuit. In some embodiments, the micro-device comprises connection posts electrically connected to the TFT circuit.

In some embodiments, the TFT circuit comprises signal selection circuitry. In some embodiments, the micro-circuit comprises LED driving circuitry, or both.

The TFT circuit can comprise a thin-film capacitor and the micro-circuit can be responsive to the charge stored in the thin-film capacitor. The micro-circuit can be responsive to a voltage provided by the TFT circuit. The micro-circuit can comprise a storage device and the storage device can store a value corresponding to a value provided by the TFT circuit.

According to embodiments of the present disclosure, the micro-device comprises a micro-device tether, the LED comprises an LED tether, or both.

According to some embodiments, a hybrid-control cluster comprises a TFT substrate, a TFT circuit formed on or in the TFT substrate, a micro-device comprising an integrated-circuit substrate non-native to (e.g., separate and independent from) the TFT substrate and a micro-circuit electrically connected to the TFT circuit, and LEDs electrically connected to the micro-circuit or the TFT circuit. The TFT circuit and the micro-circuit can be operable to control the LEDs. The micro-circuit can be a cluster controller and the cluster controller can provide passive-matrix or active-matrix control to the LEDs. The micro-device can be disposed on the TFT substrate or on a pixel substrate with one or more of the LEDs disposed on the TFT substrate.

According to embodiments of the present disclosure, a hybrid-control display comprises an array of hybrid-control pixels disposed on the TFT substrate and a display controller operable to control the array of hybrid-control pixels.

According to embodiments of the present disclosure, a hybrid-control pixel backplane comprises mass-transferrable micro-integrated circuits (microICs). In some embodiments, an OLED display comprises the hybrid-control pixel backplane.

In some embodiments, a thin-film-transistor (TFT) backplane comprises mass-transferrable micro-integrated circuits (microICs). An OLED display can comprise the thin-film-transistor (TFT) backplane.

In some embodiments, an OLED display comprises hybrid control pixels, hybrid control clusters, or a hybrid control display.

According to embodiments of the present disclosure, the TFT circuit comprises multiple thin-film capacitors controlled by common control wires and the display controller is operable to sequentially provide pixel data to the multiple thin-film capacitors. In some embodiments, the micro-circuit comprises multiple storage devices and the display controller is operable to sequentially provide pixel data to the micro-circuit.

According to some embodiments of the present disclosure, a hybrid-control pixel comprises an indium-gallium-zinc oxide (IGZO) TFT circuit native to (e.g., formed in or on) a TFT substrate, a light emitter, and a micro-device comprising a driving circuit electrically connected to the TFT circuit. The micro-device can be non-native to the TFT substrate, and the driving circuit can be responsive to the TFT circuit to drive the light emitter. The TFT circuit can be a pixel TFT circuit and can comprise a capacitor to which the driving circuit is responsive. The light emitter can be non-native to the TFT substrate, the light emitter can be an organic light-emitting diode, or the light emitter can be an inorganic light-emitting diode.

According to some embodiments of the present disclosure, a hybrid-control display comprises an indium-gallium-zinc oxide (IGZO) TFT circuit formed in or on a TFT substrate, an array of pixels, and an array of micro-devices, each of the micro-devices comprising a driving circuit electrically connected to the TFT circuit. The micro-devices can be non-native to the TFT substrate, and the micro-devices can be responsive to the TFT circuit to drive the pixels. Each of the pixels can comprise an organic light-emitting diode or an inorganic light-emitting diode.

The TFT circuit can comprise an array of pixel TFT circuits, each a part of a pixel so that the TFT circuit is a pixel TFT circuit. Similarly, each pixel can comprise a micro-device that is a part of a pixel so that the micro-device is a pixel micro-device. Each pixel TFT circuit can comprise one or more capacitors that store a charge. The one or more capacitors can be thin-film capacitors native to (e.g., formed in or on) the TFT substrate or the one or more capacitors can be micro-transfer printed onto and electrically connected to the pixel TFT circuit on the TFT substrate so that the capacitors are not native to the TFT substrate. The capacitor(s) can store analog values. Each micro-device in a pixel can comprise a storage device, e.g., a storage element such as a register, flip-flop, or memory, that can store digital values.

In some embodiments, the pixels are non-native to a display substrate, for example the pixels are disposed on a pixel substrate that is disposed on the display substrate. In some such embodiments, the TFT substrate can be the pixel substrate. The pixel TFT circuit can be native to (e.g., formed in or on) the pixel substrate. The pixel substrate can be an amorphous material substrate such as glass or plastic and the TFT circuit can be a thin-film semiconductor circuit disposed on the amorphous material. The micro-device can be disposed on the pixel substrate.

Each of the pixels can comprise a light emitter that is non-native to the TFT substrate.

According to embodiments of the present disclosure, a hybrid-control pixel comprises a low-temperature polycrystalline silicon (LTPS) TFT circuit native to (e.g., formed in or on) a TFT substrate, a light emitter, and a micro-device comprising a storage device electrically connected to the TFT circuit. The micro-device can be non-native to the TFT substrate and the storage device can be responsive to the TFT circuit to store one or more values for controlling the light emitter. The storage device can be operable to store one or more digital values. The TFT circuit can comprise a driving circuit operable to drive the light emitter responsive to the micro-device and the TFT circuit. The light emitter can be an organic or an inorganic light-emitting diode.

According to embodiments of the present disclosure, a hybrid-control display comprises a low-temperature polycrystalline silicon (LTPS) TFT circuit native to (e.g., formed in or on) a TFT substrate, an array of pixels, and an array of micro-devices, each of the micro-devices comprising a storage device electrically connected to the TFT circuit. The micro-devices can be non-native to the TFT substrate and the micro-devices can be responsive to the TFT circuit to store one or more values for controlling the light emitter. Each of the pixels can comprise an organic or an inorganic light-emitting diode. The pixels can be non-native to the TFT substrate. Each of the pixels can comprise a light emitter that is non-native to the TFT substrate. The storage device can be operable to store one or more digital values.

According to embodiments of the present disclosure, a hybrid-control pixel comprises a low-temperature polycrystalline oxide (LTPO) TFT circuit native to (e.g., formed in or on) a TFT substrate, a light emitter, and a micro-device comprising a micro-circuit electrically connected to the TFT circuit. The micro-device can be non-native to the TFT substrate and the micro-circuit and the TFT circuit can be together operable to control the light emitter.

The TFT substrate can be a display substrate or one or more pixel substrates disposed on a display substrate, e.g., each pixel in an array of pixels can comprise a pixel substrate that can be a TFT substrate. Any one or all of pixel substrates, micro-devices, light emitters, and capacitors can be micro-transfer printed devices that comprise a broken (e.g., fractured) or separated tether.

According to embodiments of the present disclosure, a hybrid-control circuit comprises a TFT substrate, a TFT circuit formed in or on the TFT substrate, and a micro-device comprising an integrated-circuit substrate separate and independent from the TFT substrate disposed on or over the TFT substrate. A micro-circuit can be formed in or on the integrated-circuit substrate of the micro-device electrically connected to the TFT circuit. The TFT circuit can comprise a thin-film capacitor formed on the TFT substrate and the micro-circuit can be responsive to the thin-film capacitor.

In one aspect, the disclosed technology includes a structure including a light-emitting diode (LED) having a first electrode, one or more layers of material (e.g., organic or inorganic material) disposed on at least a portion of the first electrode, and a second electrode disposed on at least a portion of the one or more layers of material. In certain embodiments, at least a portion of the first or second electrodes is transparent. In certain embodiments, layers of inorganic material comprise crystalline compound semiconductor material and layers of organic material comprise one or more of a hole-injection layer, a light-emitting layer, and an electron-injection layer.

In certain embodiments, the LED has a light-emitting area that has a dimension parallel to the first electrode that is less than or equal to 40 microns, less than or equal to 20 microns, less than or equal to 10 microns, or less than or equal to 5 microns. In certain embodiments, the LED has a light-emitting area that is less than or equal to 1600 square microns, less than or equal to 800 square microns, less than or equal to 400 square microns, less than or equal to 200 square microns, less than or equal to 100 square microns, or less than or equal to 50 square microns. In certain embodiments, the light emitting diode has at least one of a width from 5 to 10 μm, 10 to 20 μm, or 20 to 50 μm, a length from 5 to 10 μm, 10 to 20 μm, or 20 to 50 μm, and a height from 2 to 5 μm, 4 to 10 μm, 10 to 20 μm, or 20 to 50 μm. In certain embodiments, at least one of the one or more layers of material emits red light, green light, or blue light.

In some embodiments, at least a portion of an LED tether extends from a periphery of the light-emitting diode. In certain embodiments, the portion of an LED tether extending from the periphery of the light-emitting diode is a portion of a broken (e.g., fractured) or separated LED tether.

In some embodiments, at least a portion of a micro-device tether extends from a periphery of the micro-device. In certain embodiments, the portion of a micro-device tether extending from the periphery of the micro-device is a portion of a broken (e.g., fractured) or separated micro-device tether.

In certain embodiments, a substrate (e.g., a TFT substrate or display substrate) has a thickness from 5 to 10 μm, 10 to 50 μm, 50 to 100 μm, 100 to 200 μm, 200 to 500 μm, 500 μm to 0.5 mm, 0.5 to 1 mm, 1 mm to 5 mm, 5 mm to 10 mm, or 10 mm to 20 mm. In certain embodiments, the substrate comprises a polymer, plastic, resin, polyimide, PEN, PET, metal, metal foil, glass, a semiconductor, or sapphire. In certain embodiments, the substrate has a transparency greater than or equal to 50%, 80%, 90%, or 95% for visible light. In certain embodiments, the light-emitting diode, when energized, emits light in a direction opposite the substrate.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1 is a cross section of hybrid-control pixels each comprising an LED native to an integrated-circuit micro-device with connection posts micro-transfer printed to a common substrate according to illustrative embodiments of the present disclosure;

FIG. 2 is a cross section of hybrid-control pixels each comprising an integrated-circuit micro-device without connection posts disposed on a common substrate and an LED with connection posts non-native to the micro-device micro-transfer printed to the micro-device according to illustrative embodiments of the present disclosure;

FIGS. 3A-3C are cross sections of hybrid-control pixels each comprising an integrated-circuit micro-device without connection posts micro-transfer printed to a common display substrate and LEDs disposed on a display substrate according to illustrative embodiments of the present disclosure;

FIG. 4 is a cross section of a hybrid-control pixel comprising multiple LEDs with connection posts micro-transfer printed and non-native to the micro-device according to illustrative embodiments of the present disclosure;

FIGS. 5A-5C are electronic circuit schematics of a TFT circuit, a thin-film capacitor, a micro-circuit, and an LED according to illustrative embodiments of the present disclosure;

FIGS. 6A-6C are electronic circuit schematics of a TFT circuit, a micro-circuit with storage devices, and an LED according to illustrative embodiments of the present disclosure;

FIG. 7 is a schematic of a display comprising hybrid-control pixels in a display area according to illustrative embodiments of the present disclosure;

FIG. 8 is a schematic of a hybrid-control pixel comprising a TFT circuit with multiple thin-film capacitors, a micro-device, and multiple LEDs according to illustrative embodiments of the present disclosure;

FIG. 9 is a schematic of a hybrid-control pixel comprising a TFT circuit, a micro-circuit with multiple storage devices, and multiple LEDs according to illustrative embodiments of the present disclosure;

FIG. 10 is a schematic of a display comprising clusters of light-emitters controlled by a cluster controller using hybrid-control circuits in a display area according to illustrative embodiments of the present disclosure; and

FIGS. 11A-11D are flow diagrams according to construction methods of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not necessarily drawn to scale. The vertical scale of the Figures can be exaggerated to clarify the illustrated structures.

### DETAILED DESCRIPTION OF CERTAIN EMBODIMENTS

According to embodiments of the present disclosure, among other things, a hybrid-control pixel comprises a circuit including a thin-film transistor (TFT) circuit native to (e.g., formed in or on) a TFT substrate and a micro-device with a micro-circuit formed in an integrated circuit with a substrate separate, distinct, independent, and different from the TFT substrate. The hybrid-control pixel can comprise a light-emitting diode (LED) and the TFT circuit and micro-circuit can together in combination control the LED or another device. The micro-device can be a photolithographically processed crystalline semiconductor integrated circuit disposed on and non-native to the TFT substrate. The micro-circuit in the integrated circuit can be electrically connected to the TFT circuit. Such a hybrid-control circuit comprising both a thin-film semiconductor circuit and a micro-circuit in a crystalline semiconductor integrated circuit can effectively and efficiently apply efficient and low-cost thin-film semiconductor circuits and processes in combination with high-performance crystalline semiconductor integrated circuit micro-devices (e.g., LEDs or other devices). In particular, large charge-storage capacitors are more easily constructed in thin-film structures on a TFT substrate than in integrated circuits and drive circuits in a crystalline semiconductor integrated circuit responsive to charges stored in the thin-film capacitor can be smaller, can be more complex, and can have higher performance.

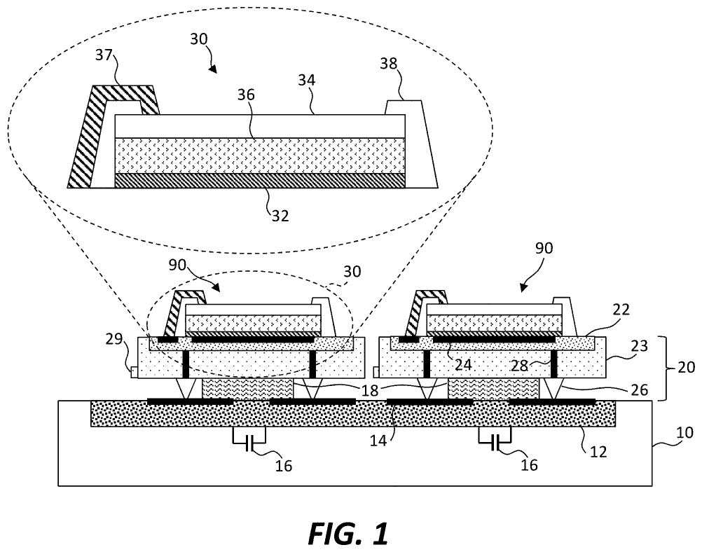

According to embodiments of the present disclosure and as illustrated in FIGS. 1-4, a hybrid-control pixel 90 comprises a TFT substrate 10 (e.g., a substrate with a thin-film coating of semiconductor material suitable for patterned thin-film transistors 44), a TFT circuit 12 native to (e.g., formed in or on) TFT substrate 10, a micro-device 20 comprising an integrated-circuit substrate 23 separate and independent from TFT substrate 10, a micro-circuit 22 native to (e.g., formed in or on) integrated-circuit substrate 23 electrically connected to TFT circuit 12, and an LED 30 disposed on micro-device 20, TFT substrate 10, or another substrate, for example a pixel substrate on which is disposed both LED 30 and micro-device 20. The pixel substrate can be disposed on TFT substrate 10. LED 30 can be electrically connected to micro-circuit 22 or TFT circuit 12, or both. TFT circuit 12 and micro-circuit 22 can be operable together and in combination to control LED 30 or another device. Micro-device 20 can be disposed on or over TFT substrate 10 or on TFT circuit 12.

LED 30 can be an organic light-emitting diode (OLED) 30 or an inorganic light-emitting diode (iLED) 30. LED 30 can comprise electrical conductors (e.g., anode 32 and cathode 34) for providing electrical current at a suitable voltage to operate LED 30 and light-emitting material 36 (e.g., doped or undoped crystalline semiconductor material for an iLED 30 or layers of coated materials for an OLED 30, for example hole-injection, electron-injection, and light-emitting layers). One or more LED electrodes 37 can be insulated from light-emitting material 36 with dielectric structures 38 and electrically connected to anode 32, cathode 34, or micro-circuit 22. Micro-circuit 22 can electrically connect to anode 32 (as shown) or cathode 34 through micro-circuit contact pad 24. TFT circuit 12 can be electrically connected to micro-circuit 22 through TFT contact pads 14 disposed on TFT substrate 10 (e.g., electrical contact pads formed in the thin-film layer on TFT substrate 10).

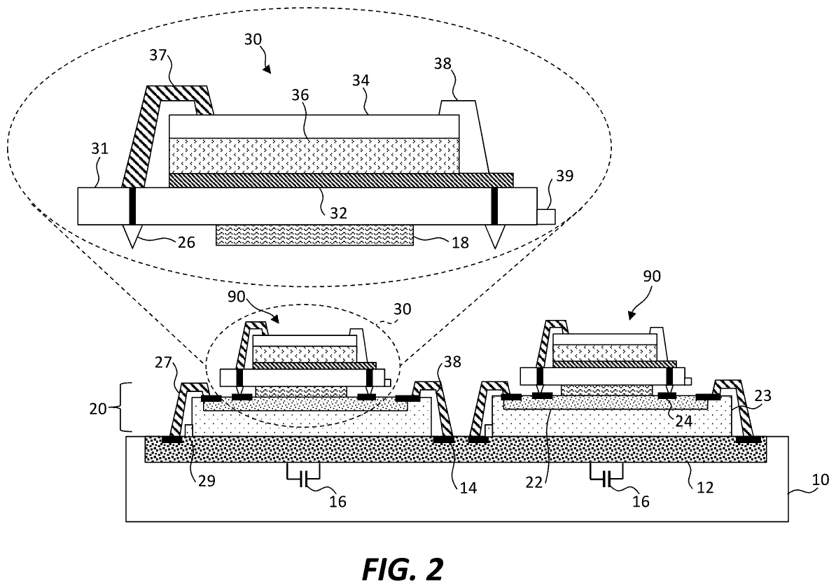

Micro-devices 20 can be micro-transfer printed onto TFT substrate 10 and, adjacent to or directly on or over TFT circuit 12. As a consequence of micro-transfer printing, micro-devices 20 can comprise a micro-device tether 29, as shown in FIG. 1. Similarly, LED 30 can comprise an LED substrate 31 and can be micro-transfer printed directly, for example, onto micro-device 20 or TFT substrate 10, and consequently comprise an LED tether 39, as shown in FIG. 2. In some embodiments, LED 30 can be native to (e.g., formed in or on) micro-device 20, as shown in FIG. 1.

LED 30 can be electrically connected to micro-circuit contact pads 24 such as electrical contact pads provided in micro-device 20 and electrically connected to micro-circuit 22 of micro-device 20 with electrical connections such as LED electrodes 37 formed using photolithographic methods and materials (e.g., metal evaporation or sputtering and patterning using photoresists, masks, and etching), as shown in FIG. 1. Similarly, micro-devices 20 can be electrically connected to TFT circuit 12 on TFT substrate 10 through TFT contact pads 14 with electrical connections such as micro-device electrodes 27 formed using photolithographic methods and materials, as shown in FIG. 2.

In some embodiments, micro-devices 20 can be electrically connected to TFT circuit 12 on TFT substrate 10 through TFT contact pads 14 with electrical connections made through connection posts 26 connected to micro-circuit 22, for example through electrical vias 28 in integrated-circuit substrate 23, as shown in FIG. 1. Connection posts 26 can be electrically conductive structures that extend from integrated-circuit substrate 23 and are electrically connected to micro-circuit 22 or LED electrodes 37 through electrical vias 28. The construction and micro-transfer printing of devices with connection posts 26 is described in more detail in U.S. Pat. No. 10,468,363, entitled Chiplets with Connection Posts. Micro-devices 20 with connection posts 26 can be micro-assembled on TFT substrate 10 and electrically connected to TFT contact pads 14 by micro-transfer printing. Micro-devices 20 with or without connection posts 26 can be adhered to TFT substrate 10 with a patterned layer of adhesive 18.

Similarly, in some embodiments and as shown in FIG. 2, LEDs 30 can comprise connection posts 26 electrically connected to cathode 34 and anode 32 and can be micro-assembled on micro-device 20 and electrically connected to micro-circuit contact pads 24 by micro-transfer printing. LEDs 30 with or without connection posts 26 can be adhered to micro-device 20 with a patterned layer of adhesive 18. In some embodiments, LEDs 30 are assembled on micro-devices 20 and micro-devices 20 with LEDs 30 are assembled on TFT substrate 10. In some embodiments, micro-devices 20 with LEDs 30 are assembled on TFT substrate 10 and then LEDs 30 are assembled on micro-devices 20 or on TFT substrate 10. In some embodiments, micro-devices 20 with LEDs 30 are assembled on TFT substrate 10 or LEDs 30 are assembled on TFT substrate 10.

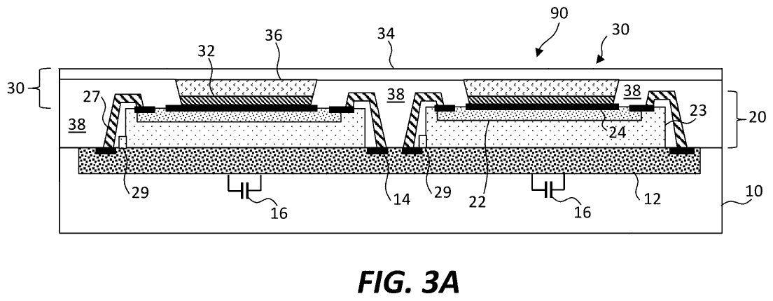

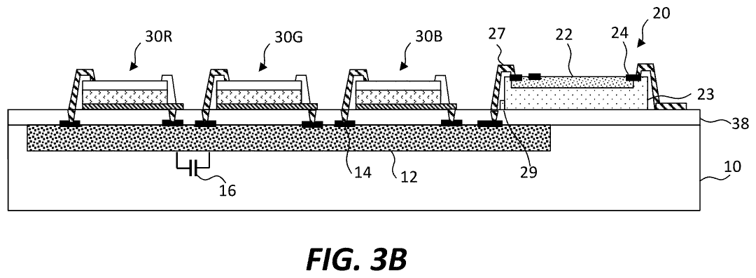

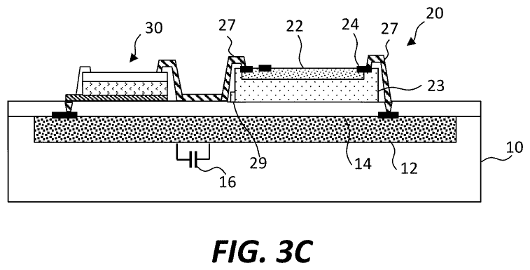

In some embodiments and as illustrated in FIG. 3A, LEDs 30 can each comprise an anode 32 coated on each micro-device 20 and light-emitting material 36 coated on anodes 32. A cathode 34 common to all of LEDs 30 can be coated over light-emitting material 36. LEDs 30 (e.g., OLEDs 30) can be native to micro-device 20. Common cathode 34 can be electrically connected to TFT circuit 12 externally to micro-devices 20 or can be connected to microdevices 20 (not shown in FIG. 3A). In some embodiments and as shown in FIG. 3B, LEDs 30 (e.g., OLED layers 36 for red LED 30R, green LED 30G, and blue LED 30B) are coated over a dielectric structure 38 (e.g., a layer) on TFT substrate 10 and electrically connected through electrical vias 28 to TFT circuit 12. In some embodiments, cathode 34 is commonly connected as in FIG. 3A and can be connected to micro-circuit 22 (not shown in FIG. 3B). Micro-circuit 22 in micro-device 20 is likewise electrically connected to TFT circuit 12 but not directly to LEDs 30. In some embodiments and as shown in FIG. 3C, LEDs 30 (e.g., OLED layers 36) are coated over a dielectric structure 38 (e.g., a layer) and electrically connected through electrical vias 28 to micro-circuit 22 in micro-device 20. TFT circuit 12 is likewise electrically connected to micro-circuit 22 and directly or indirectly (e.g., through another circuit element) to LEDs 30.

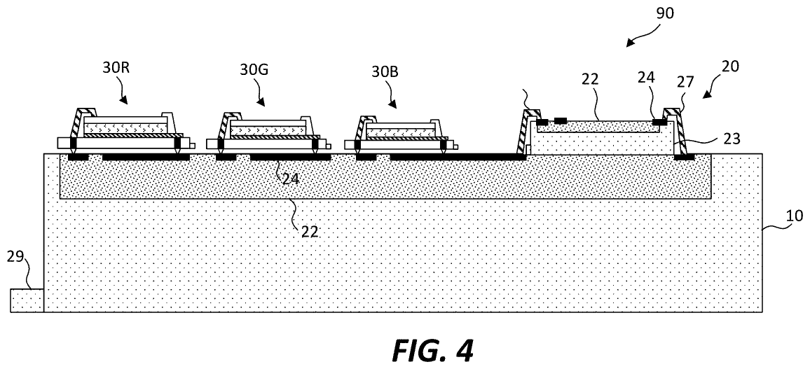

In some embodiments and as shown in FIG. 4, hybrid-control pixels 90 comprise multiple LEDs 30, for example a red LED 30R operable to emit red light, a green LED 30G operable to emit green light, and a blue LED 30B operable to emit blue light. Red, green, and blue LEDs 30R, 30G, 30B (collectively LEDs 30) can be electrically connected to micro-circuit 22 through LED electrodes 37 directly connected to micro-circuit contact pads 24 with photolithographically defined electrical connectors (as shown in FIG. 1) or through connection posts 26 (as shown in FIGS. 2 and 4). The multiple LEDs 30 can be comprised in a hybrid-control pixel 90 and a hybrid-control display 92 can comprise multiple hybrid-control pixels 90.

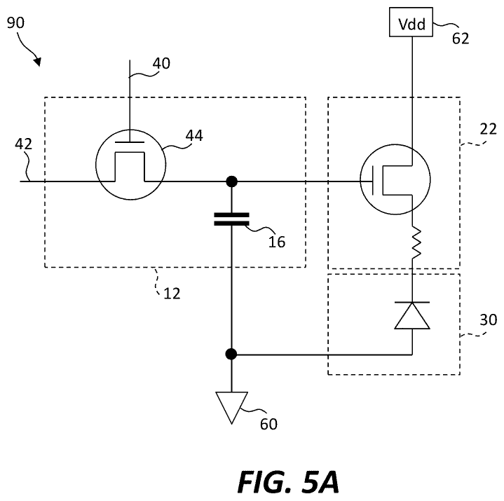

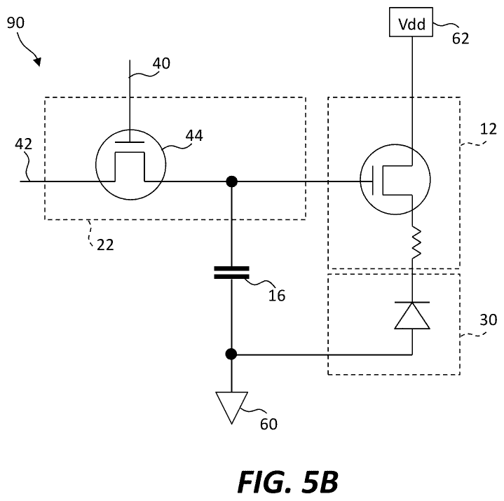

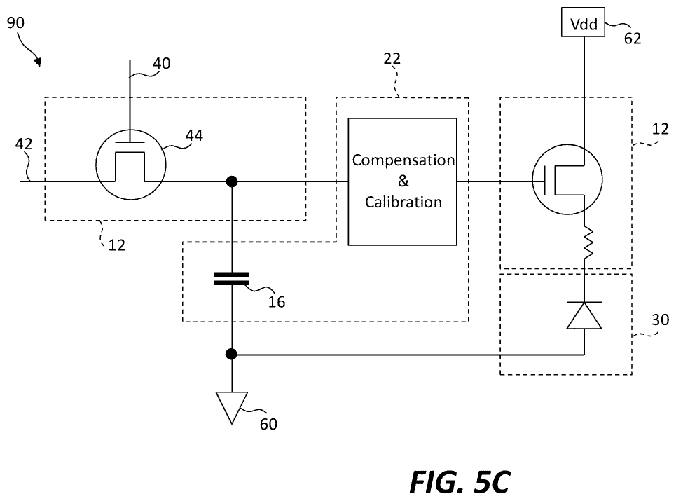

According to some embodiments of the present disclosure and as shown in FIGS. 5, 6, and 7 active-matrix or passive-matrix circuits useful for hybrid-control pixels 90 can comprise TFT circuit 12 native to (e.g., formed in or on) TFT substrate 10 and micro-circuit 22 native to (e.g., formed in or on) integrated-circuit substrate 23 of micro-device 20. In some embodiments, TFT circuit 12 can comprise a circuit for receiving and selecting control signals and micro-circuit 22 can respond to the selected control signal, for example to operate an LED 30 or other device disposed on or over micro-device 20 or micro-circuit 22. In some embodiments, micro-circuit 22 can comprise a circuit for receiving and selecting control signals and TFT circuit 12 can respond to the selected control signal, for example to operate an LED 30 or other device disposed on micro-device 20 or micro-circuit 22. In some embodiments, TFT circuit 12 can comprise a circuit for receiving and selecting control signals and operating an LED 30 or other device disposed on or over micro-device 20 or micro-circuit 22 and micro-circuit 22 can provide control, calibration, or compensation functions.

As shown in the select circuit of FIG. 5A in an active-matrix embodiment, the row-select signal on row-select wire 40 can turn on a thin-film transistor 44 of TFT circuit 12 to receive a column-data signal on column-data wire 42 and store the received signal (voltage) in a capacitor 16 (e.g., a thin-film capacitor 16 or a micro-transfer printed capacitor 16 disposed on display substrate 10). The stored voltage is then transmitted to micro-circuit 22. Micro-circuit 22 responds to the stored voltage to control electrical power, for example a current, that is provided to LED 30 or an other device. FIG. 5A illustrates a simple transistor controlled by capacitor 16 voltage to provide electrical current to LED 30 in micro-circuit 22, but in some other embodiments, micro-circuit 22 comprises a much more sophisticated and complex micro-circuit 22, for example providing a current whose magnitude is directly responsive to the voltage across capacitor 16 that is substantially invariant or has reduced variance in the presence of heat variation, ground 60 voltage variation, and Vdd 62 voltage (power) variation in hybrid-control pixels 90 or in LED 30 light-emitting material 36 variation across TFT substrate 10. For example, micro-circuit 22 can provide compensation or calibration to hybrid-control pixel 90, e.g., self-compensation or self-calibration.

Capacitance in capacitor 16 varies with the area of capacitor 16 parallel plates. Larger capacitors 16 storing more charge can provide a micro-circuit 22 control signal that has a greater range with less noise. Thus, according to embodiments of the present disclosure, larger capacitors 16 can be preferred but making large capacitors 16 in integrated circuit micro-devices 20 can be problematic since it can be desirable to make micro-devices 20 as small as possible to reduce cost. At the same time, micro-circuits 22 with small elements (e.g., transistors and wires) enable more complex and sophisticated circuits in a small area. Hence, according to embodiments of the present disclosure, capacitor 16 can be a thin-film capacitor 16 disposed in TFT circuit 12 on TFT substrate 10 and micro-circuit 22 responsive to a signal (e.g., voltage or charge) provided by capacitor 16 can be disposed in integrated circuit micro-device 20 to drive LED 30 with LED driving circuitry, e.g., micro-circuit 22 in a crystalline semiconductor integrated-circuit substrate 23. Moreover, providing a signal selection function in TFT circuit 12 reduces the number of connections to micro-device 20 since the selection function requires two signals (the row-select signal and the column-data signal) and only one signal is provided to micro-circuit 22 (e.g., the voltage control signal from capacitor 16), improving manufacturing yields for micro-device 20 interconnects.

FIG. 5B illustrates embodiments in which micro-circuit 22 provides communication and control functions, e.g., receives the row-select signal on row-select wire 40 and receives the column-data signal on column-data wire 42 and stores the received signal (voltage) in a capacitor 16 (e.g., a thin-film capacitor 16 external to TFT circuit 12 and micro-circuit 22 as shown, a micro-transfer printed capacitor 16 disposed on display substrate 10, or a capacitor 16 integrated into micro-circuit 22, not shown in FIG. 5B). TFT circuit 12 responds to the stored voltage to control electrical power, for example a current, that is provided to LED 30 or another device.

FIG. 5C illustrates embodiments in which TFT circuit 12 provides communication and control functions, e.g., receives the row-select signal on row-select wire 40, receives the column-data signal on column-data wire 42, and stores the received signal (voltage) in a capacitor 16 (e.g., a micro-transfer printed capacitor 16 disposed on display substrate 10 or a capacitor 16 integrated into micro-circuit 22, as shown in FIG. 5C, or a thin-film capacitor 16 that can be a part of TFT circuit 12, not shown in FIG. 5C). Micro-circuit 22 controls, for example compensates or calibrates, the received signal, for example to adjust performance based on thermal considerations, differences in LED 30 performance, voltage variation, and the like.

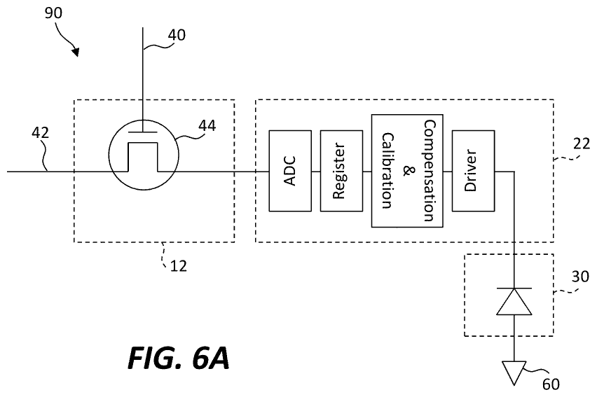

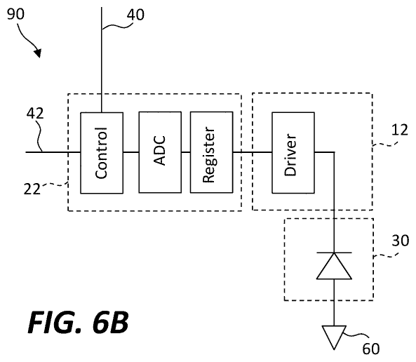

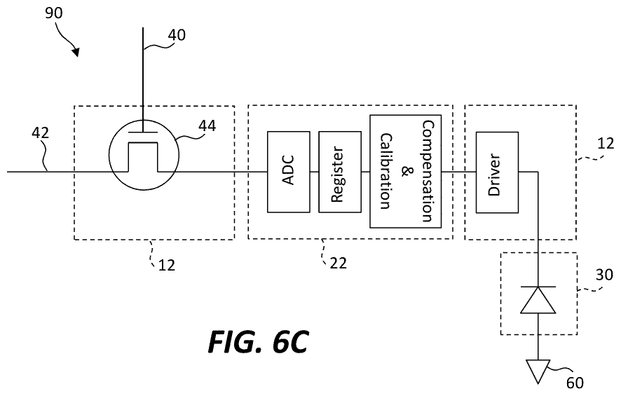

FIG. 6A illustrates embodiments of the present disclosure in which TFT circuit 12 does not comprise capacitor 16. In such an embodiment, a voltage provided on column-data wire 42 is selected by thin-film transistor 44 and received directly by micro-circuit 22. Micro-circuit 22 converts the voltage to a digital value with an analog-to-digital converter (ADC) and stores the digital value in a register or other digital storage device (e.g., a memory such as a flip flop or static memory element). Micro-circuit 22 can compensate or calibrate the digital value. The digital value is then provided to a driver (e.g., a driving micro-circuit 22 responsive to the stored digital value to provide a desired electrical signal such as a current) that controls light output from LED 30. This structure corresponds to the circuit diagram of FIG. 5A without capacitor 16.

FIG. 6B illustrates embodiments of the present disclosure in which micro-circuit 22 selected by the row-select signal on row-select wire 40 directly receives a voltage or digital signal provided on column-data wire 42. Micro-circuit 22 converts the voltage to a digital value with an analog-to-digital converter (ADC) and stores the digital value in a register or other digital storage device (e.g., a memory such as a flip flop or static memory element) or receives a digital signal and stores the digital signal (digital value) in a register or other digital storage device. Micro-circuit 22 can compensate or calibrate the digital value. The digital value is then provided to a driver (e.g., a driving TFT circuit 12 responsive to the digital value to provide a desired electrical signal such as a current) that controls light output from LED 30. This structure corresponds to the circuit diagram of FIG. 5B without capacitor 16.

FIG. 6C illustrates embodiments of the present disclosure in which a voltage provided on column-data wire 42 is selected by thin-film transistor 44 and received directly by micro-circuit 22. Micro-circuit 22 converts the voltage to a digital value with an analog-to-digital converter (ADC) and stores the digital value in a register or other digital storage device (e.g., a memory such as a flip flop or static memory element). Micro-circuit 22 can compensate or calibrate the digital value. The digital value is then provided to a driver (e.g., a driving TFT circuit 12 responsive to the digital value to provide a desired electrical signal such as a current) that controls light output from LED 30. This structure corresponds to the circuit diagram of FIG. 5C without capacitor 16.

The embodiments of FIGS. 6A-6C can comprise a digital-to-analog conversion circuit, for example in micro-circuit 22 to convert the digital value to a signal (e.g., a current) suitable for driving LED 30.

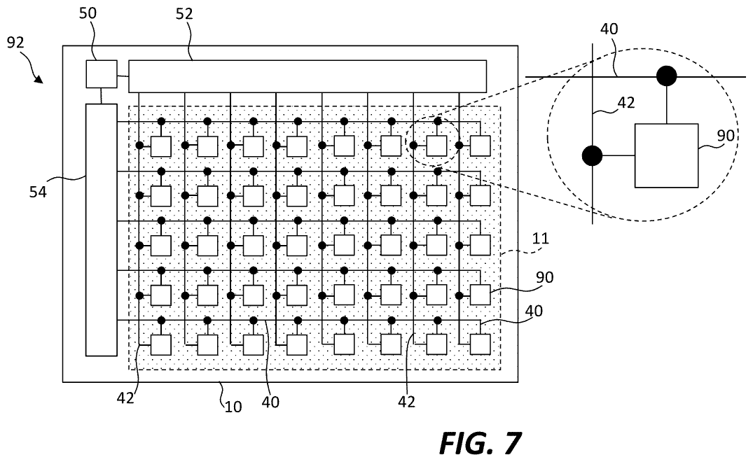

As shown in FIG. 7, hybrid-control pixels 90 are disposed in an array, for example in rows and columns on TFT substrate 10 (a display substrate 10) in a display area 11. Each row of hybrid-control pixels 90 is connected to a row-select wire 40 that transmits row-control signals from a row controller 54. Each column of hybrid-control pixels 90 is connected to a column-data wire 42 that transmits column-data signals from a column controller 52. Electrical connections between wires are shown with dots in FIG. 7. Display controller 50 is operable to send display control signals to row controller 54 and column controller 52. In some embodiments, row controller 54 and column controller 52 are a part of or are included in display controller 50. Row controller 54 can send a row-select signal on one row-select wire 40 to a row of hybrid-control pixels 90 at the same time as column controller 52 sends column-data signals on column-data wires 42 to all of the columns of hybrid-control pixels 90, e.g., to every hybrid-control pixel 90 in the display. However, only those hybrid-control pixels 90 in the row receiving the row-select signal store the column-data signal (e.g., a voltage corresponding to a desired brightness for LED 30) in hybrid-control pixel 90. The other rows of hybrid-control pixels 90 that do not receive the row-select signal ignore the column-data signal.

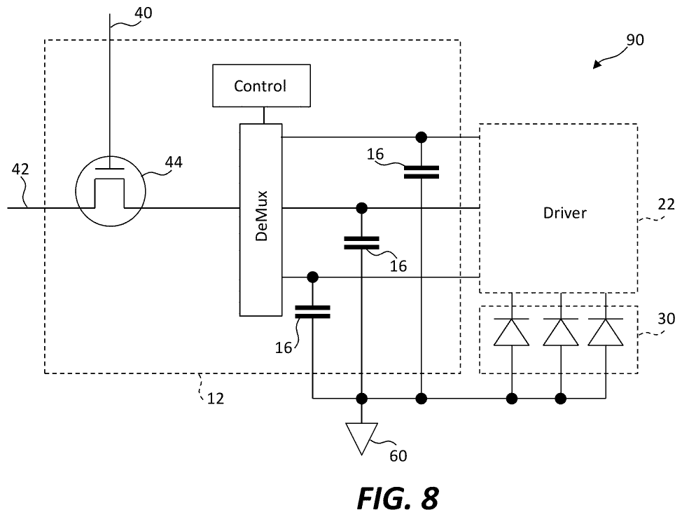

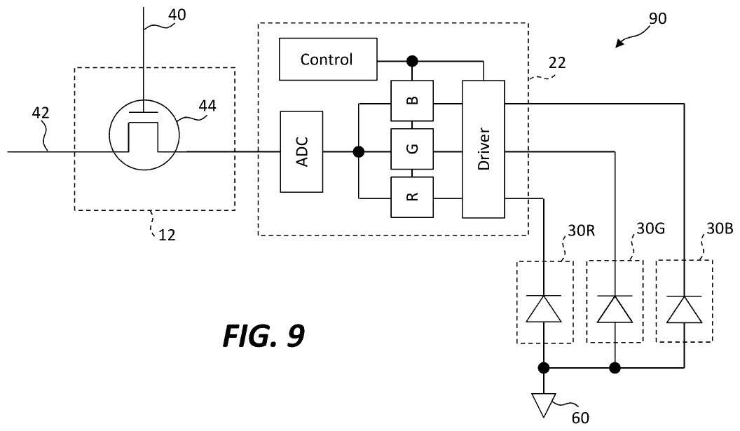

According to some embodiments of the present disclosure and as shown in FIG. 7, a hybrid-control display 92 comprises an array of hybrid-control pixels 90 disposed on TFT substrate 10 (e.g., all of hybrid-control pixels 90 are disposed on a common same TFT substrate 10) and display controller 50 is operable to control the array of hybrid-control pixels 90. Display controller 50 can comprise row controller 54 and column controller 52. As shown in FIG. 8, TFT circuit 12 can comprises multiple thin-film capacitors 16 (e.g., for storing red, green, and blue voltages for a multi-color pixel 90 comprising red, green, and blue LEDs 30R, 30G, 30B) controlled by common control wires (e.g., row-select wire 40 and column-data wire 42). Display controller 50 can be operable to sequentially provide pixel data to the multiple thin-film capacitors 16, thereby reducing the number of row-select wires 40 and column-data wires 42 on TFT substrate 10. As shown in FIG. 9, sequentially provided and selected voltage signals can be converted directly to digital values by an analog-to-digital converter and stored in registers (e.g., for storing red, green, and blue voltages or equivalent digital values for a multi-color pixel 90 comprising red, green, and blue LEDs 30R, 30G, 30B). The stored values are provided to a driver micro-circuit 22 that drives LEDs 30 to emit light corresponding to the voltages provided on column-data wire 42.

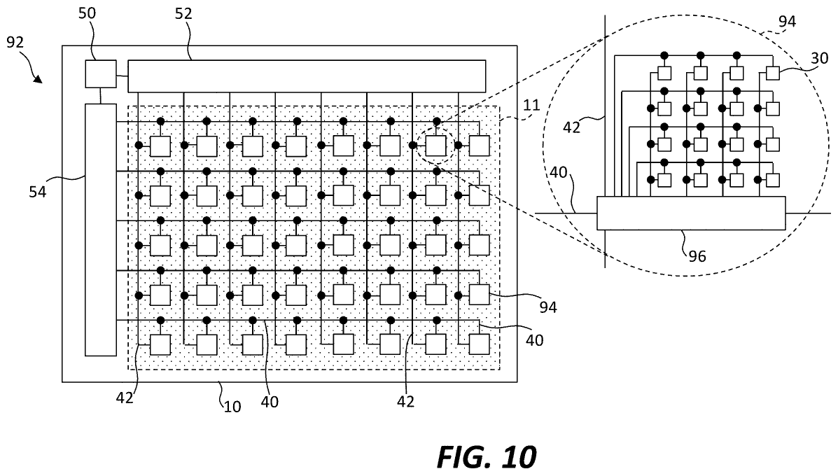

FIGS. 7-9 illustrate an active-matrix display control architecture. In some embodiments of the present disclosure and as shown in FIG. 10, pixels 90 are arranged in clusters 94 (groups) that are controlled by a cluster controller 96. Cluster controller 96 can receive active-matrix control signals for multiple groups of light-emitters 30 from display controller 50, e.g., with row controller 54 and column controller 52. The pixels 90 or light-emitters 30 (e.g., LEDs 30) are controlled by cluster controller 96 in either an active-matrix or passive-matrix architecture. Each cluster controller 96 can be a hybrid-control cluster controller 96 that comprises both a TFT circuit 12 and a micro-circuit 22. Micro-circuit 22 can be disposed in a micro-device 20. Hybrid-control cluster controller 96 can comprise any of the circuit architectures described herein, for example as illustrated and described with respect to any of FIGS. 1-9.

Embodiments of the present disclosure provide hybrid-control pixels 90 in a hybrid-control display 92. More generally and according to some embodiments of the present disclosure, a hybrid-control circuit can control any desired device and can comprise a TFT substrate 10, a TFT circuit 12 native to (e.g., formed in or on) TFT substrate 10, a micro-device 20 comprising an integrated-circuit substrate 23 separate and independent from TFT substrate 10 disposed on or over TFT substrate 10, and a micro-circuit 22 electrically connected to TFT circuit 12, for example through connection posts 26 or photolithographically formed micro-device electrodes 27. In some embodiments, TFT circuit 12 comprises a thin-film capacitor 16 formed on TFT substrate 10 and micro-circuit 22 is responsive to thin-film capacitor 16.

Some embodiments of thin-film-transistor backplanes comprise circuitry (e.g., thin-film transistors 44) made in different materials. For example, a circuit (e.g., thin-film circuit) can comprise LTPS (low-temperate polycrystalline silicon) elements (e.g., transistors) and indium-gallium-zinc-oxide (IGZO) elements (e.g., transistors). IGZO transistors can have a higher electron mobility than LTPS transistors but can also be larger. Each of the different transistors can be applied in a circuit to functions best adapted to the characteristics of the different transistors. For example, IGZO transistors can be used to drive OLEDs in an OLED display and LTPS transistors can be used for circuit communications and control. Embodiments of the present disclosure can replace IGZO transistors with micro-circuit 22, thereby further improving the performance of the hybrid circuit.

Micro-circuits 22 can operate at lower voltages than LTPS and IGZO thin-film transistors 44, can have smaller transistors with lower leakage current densities and therefore lower current leakage, and a smaller on-resistance, resulting in improved power efficiencies and speeds. Organic light-emitting diode (OLED) or iLED displays with backplanes featuring TFT circuits 12 in combination with micro-circuits 22 have various advantages such as improved display power, better color depth, better dynamic range, improved driver stability, superior self-calibration, high-resolution touch integration, and in-plane sensing. The relative overall power consumption of OLED displays according to embodiments of the present disclosure can be reduced to no more than 41% of existing OLED displays. In some embodiments, power required to emit light is reduced by at least 26% and power to control data is reduced by at least 75%, depending on design and use cases.

Some embodiments of the present disclosure comprise pixels 90 including one or more capacitors 16. In some embodiments, capacitors 16 are thin-film capacitors 16. In some embodiments, capacitors 16 are non-native (e.g., micro-transfer-printed) capacitors 16 disposed on TFT (display) substrate 20 and electrically connected to either or both of TFT circuits 12 and micro-circuits 22.

In some embodiments of the present disclosure, TFT circuits 12 and micro-circuits 22 comprise cluster controllers 96 that control a cluster 94 or group of pixels 90 or light-emitters 30 (e.g., LEDs 30). The cluster controllers 96 can be active-matrix or passive-matrix.

Elements of different implementations described herein may be combined to form other implementations not specifically set forth above. Elements may be left out of the devices described herein without adversely affecting their operation. Various separate elements may be combined into one or more individual elements to perform the functions described herein. For example, TFT circuits 12 in various embodiments can perform different functions, such as control, input, storage, or driving. Likewise, micro-circuits 22 can perform different functions, such as control, input, storage, or driving. In some embodiments, one more functions not performed with TFT circuits 12 are performed with micro-circuits 22 or vice versa.

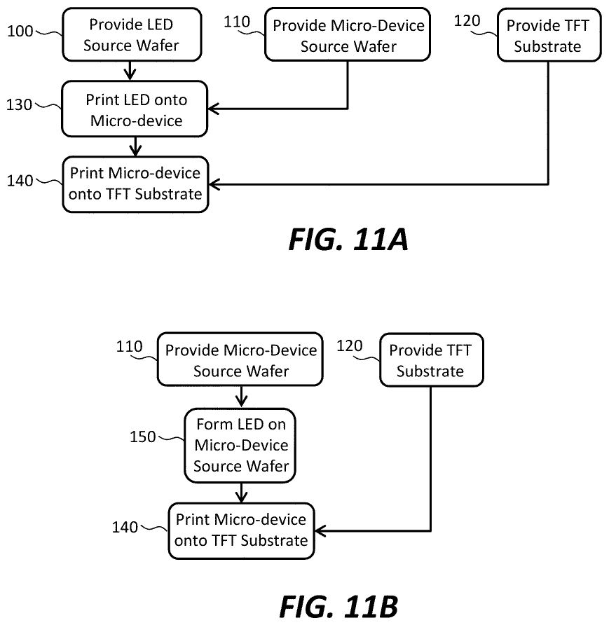

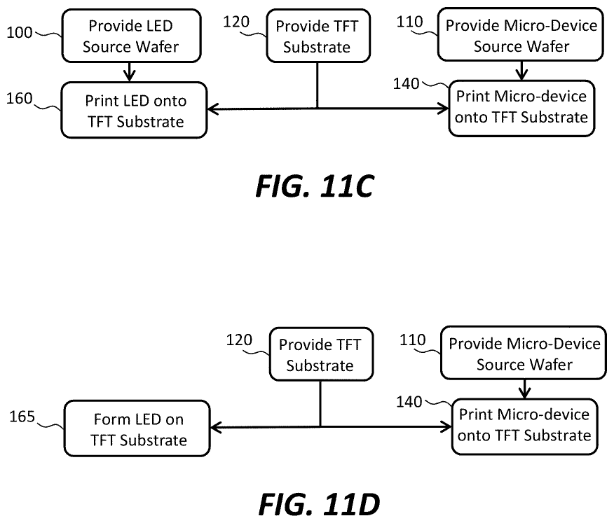

According to methods of the present disclosure, hybrid-control pixels 90 and hybrid-control displays 92 can be constructed as illustrated in FIGS. 11A-11D. As shown in FIG. 11A, an LED source wafer is provided in step 100, a micro-device source wafer is provided in step 110, and a TFT substrate is provided in step 120. In step 130, an LED 30 is micro-transfer printed onto micro-device 20 and electrically connected to micro-circuit 22 using photolithographic methods and materials or connection posts 26. In step 140, micro-device 20 with LED 30 is micro-transfer printed onto TFT substrate 10 and electrically connected to TFT circuit 12 using photolithographic methods and materials or connection posts 26. As shown in FIG. 11B, LED 30 is native to (e.g., formed in or on) micro-device 20 in step 150 and electrically connected to micro-circuit 22. In step 140, micro-device 20 with LED 30 is micro-transfer printed onto TFT substrate 10 and electrically connected to TFT circuit 12 using photolithographic methods and materials or connection posts 26. FIG. 11C illustrates embodiments in which LED 30 and micro-device 20 are independently micro-transfer printed directly to TFT substrate 10 in steps 160 and 140, respectively. LED 30 and micro-device 20 can be electrically connected to TFT circuit 22 using photolithographic methods and materials or connection posts 26. FIG. 11D illustrates embodiments in which LED 30 is native to (e.g., formed in or on) TFT substrate 10 and micro-device 20 is independently printed (e.g., micro-transfer printed) directly to TFT substrate 10 in steps 165 and 140, respectively. LED 30 and micro-device 20 can be electrically connected to TFT circuit 22 using photolithographic methods and materials or connection posts 26.

An OLED emitter typically includes several layers, for example a hole-injection layer, a light-emitting layer, and an electron-injection layer. The hole-injection layer is coated on a first electrode such as an anode 32 and a second electrode such as a cathode 34 is formed on an electron-injection layer. Alternatively, an electron-injection layer is formed on a cathode 34 and anode 32 is formed on a hole-injection layer. Inorganic LEDs 30 can comprise layers of crystalline compound semiconductors doped to facilitate electrical conduction or light emission.

Micro-device 20 can comprise a crystalline material such as a crystalline semiconductor material. Micro-device 20 can comprise a compound semiconductor material such as GaN, GaAs, or InP or a semiconductor material such as silicon. According to embodiments of the present disclosure, micro-device 20 or LED 30 can have a length or a width no greater than 1,000 μm (e.g., no greater than 750 μm, no greater than 500 μm, no greater than 200 μm, no greater than 100 μm, no greater than 50 μm, or no greater than 20 μm, or no greater than 10 μm or a thickness no greater than 100 μm (e.g., no greater than 50 μm, no greater than 20 μm, no greater than 10 μm, or no greater than 5 μm). Micro-device 20 can have a length or width no greater than a length or width of TFT circuit 12. LED 30 can have a length or width no greater than a length or width of micro-device 20. LED 30 can emit light in a direction away from micro-device 20 or TFT substrate 10.

Micro-device 20 can be disposed on TFT substrate 10 adjacent to TFT circuit 12, within a circumference of and surrounded by TFT circuit 12, or can be disposed on or over TFT circuit 12. Similarly, in some embodiments LED 30 is disposed on TFT substrate 10 and is adjacent to micro-device 20. In some embodiments, LED 30 is disposed adjacent to TFT circuit 12 on TFT substrate 10, is disposed within a circumference of and surrounded by TFT circuit 12 or is disposed on or over TFT circuit 12. LED 30 can emit light through TFT substrate 10 or in a direction away from TFT substrate 10.

Micro-device 20 can be any structure, circuit, or system useful in combination with TFT circuit 12, for example an electronic or opto-electronic device such as an active or passive integrated circuit, light-emitting diode, vertical cavity surface emitting laser (VCSEL), photodiode, or sensor. Micro-device 20 can comprise any one or more of a combination of semiconductor, conductive metals, or dielectric materials, such as inorganic oxides (e.g., silicon oxide), nitrides (e.g., silicon nitride), or organic materials such as resins or epoxies. Micro-device 20 can comprise a compound semiconductor, for example GaN, GaAs, InP, or other III/V or II/VI compound semiconductor materials. Micro-device 20 can be a silicon integrated circuit. Micro-device 20 or LED 30 can be constructed using photolithographic deposition and patterning methods and materials known in the art. Micro-device 20 can control, respond to, or interact with LED 30 or TFT circuit 12. TFT circuit 12 can comprise or be a thin-film layer of amorphous silicon, low-temperature polysilicon, or high-temperature polysilicon or other thin-film semiconductor materials or material combinations, such as zinc oxide or IGZO (indium gallium zinc oxide).

Micro-devices 20 or LEDs 30 can be micro-transfer printed with a stamp or with other transfer devices that are not a stamp. For example, in some embodiments, a transfer device that is a vacuum-based or electrostatic transfer device can be used to print micro-devices 20 or LEDs 30. A stamp, a vacuum-based transfer device, or electrostatic transfer device can comprise a plurality of transfer posts, each transfer post being constructed and arranged to pick up a single micro-device 20 or LED 30.

According to some embodiments, micro-transfer printing can include any method of transferring micro-devices 20 or LEDs 30 from a source substrate (e.g., a micro-device or LED source wafer) to a destination substrate or surface (e.g., TFT substrate 10) by contacting micro-devices 20 or LEDs 30 with a patterned or unpatterned stamp surface of a stamp to remove micro-devices 20 or LEDs 30 from a respective source substrate, transferring stamp and contacted micro-devices 20 or LEDs 30, and contacting micro-devices 20 or LEDs 30 to a surface of TFT substrate 10 or micro-device 20, respectively. Micro-devices 20 or LEDs 30 can be adhered to stamp or TFT substrate 10 by, for example, van der Waals forces, electrostatic forces, magnetic forces, chemical forces, adhesives, or any combination of the above. In some embodiments, micro-devices 20 or LEDs 30 are adhered to a stamp with separation-rate-dependent adhesion, for example kinetic control of viscoelastic stamp materials such as can be found in elastomeric transfer devices such as a PDMS stamp. Micro-transfer printing is a useful way to micro-assemble micro-structures because it can print micro-devices 20 or LEDs 30 that are smaller than other prior components using prior assembly methods, such as pick-and-place. Thus, embodiments of the present disclosure enable smaller and spatially denser micro-systems.

Patterned electrical conductors (e.g., wires, traces, or electrodes (e.g., electrical contact pads) such as those found on printed circuit boards, flat-panel display substrates, and in thin-film circuits) can be formed on any combination of micro-devices 20 and LEDs 30, as well as TFT substrate 10, and any one can comprise electrodes (e.g., electrical TFT contact pads 14, micro-circuit contact pads 24, micro-device electrodes 27, or LED electrodes 37). Such patterned electrical conductors and electrodes can comprise, for example, metal, transparent conductive oxides, or cured conductive inks and can be constructed using photolithographic methods and materials, for example metals such as aluminum, gold, or silver deposited by evaporation and patterned using pattern-wise exposed, cured, and etched photoresists, or constructed using imprinting methods and materials or inkjet printers and materials, for example comprising cured conductive inks deposited on a surface or provided in micro-channels, or both.

Adhesive 18 can be a curable or cured adhesive 18. Adhesive 18 can be an uncured adhesive 18 that is subsequently cured. Uncured adhesive 18 can be deposited on TFT substrate 10 as a liquid, and optionally on micro-device 20 or LED 30, for example by laminating, coating, inkjet printing, or spraying adhesive 18. Adhesive 18 can be a soft-cured adhesive 18, for example an adhesive 18 from which at least some, a majority, or a substantial majority of solvents or other volatile materials are evaporated or otherwise removed or driven out from uncured adhesive 18 that is still relatively malleable, compliant, or conformable compared to a hard-cured adhesive 18 and can be shaped or otherwise deformed by pressing against the soft-cured adhesive 18, for example with a micro-device 20 or LED 30. An uncured or soft-cured adhesive 18 can be hard cured, for example by heating or exposure to electromagnetic radiation that renders adhesive 18 a cured, relatively rigid, non-compliant, non-conformable, and solid adhesive 18 with substantially reduced stickiness or adhesion compared to uncured or soft-cured adhesive 18. Thus, in some embodiments, adhesive 18 can be completely uncured, soft-cured, or hard-cured at various stages of constructing hybrid-control pixels 90 or hybrid-control displays 92 of the present disclosure. A layer of soft-cured (e.g., partially cured) adhesive 18 can be patterned, for example by photolithographic processing using masks to expose the layer of uncured adhesive 18 and removing either the exposed or unexposed adhesive 18 to form a patterned layer of soft-cured adhesive 18 on TFT substrate 10. According to embodiments of the present disclosure, adhesive 18 can comprise an organic material, a polymer, a resin, or an epoxy. According to some embodiments, adhesive 18 is a photoresist.

Examples of micro-transfer printing processes suitable for disposing micro-devices 20 onto TFT substrate 10 or LEDs 30 onto micro-devices 20 or TFT substrate 10 are described in Inorganic light-emitting diode displays using micro-transfer printing (Journal of the Society for Information Display, 2017, DOI #10.1002/jsid.610, 1071-0922/17/2510-0610, pages 589-609), U.S. Pat. No. 8,722,458 entitled Optical Systems Fabricated by Printing-Based Assembly, U.S. patent application Ser. No. 15/461,703 entitled Pressure-Activated Electrical Interconnection by Micro-Transfer Printing, U.S. Pat. No. 8,889,485 entitled Methods for Surface Attachment of Flipped Active Components, U.S. patent application Ser. No. 14/822,864 entitled Chiplets with Connection Posts, U.S. patent application Ser. No. 14/743,788 entitled Micro-Assembled LED Displays and Lighting Elements, and U.S. patent application Ser. No. 15/373,865, entitled Micro-Transfer Printable LED Component, the disclosure of each of which is incorporated herein by reference in its entirety. Examples of micro-transfer printed acoustic wave filter devices are described in U.S. patent application Ser. No. 15/047,250, entitled Micro-Transfer Printed Acoustic Wave Filter Device, the disclosure of which is incorporated herein by reference in its entirety.

For a discussion of various micro-transfer printing techniques, see also U.S. Pat. Nos. 7,622,367 and 8,506,867, each of which is hereby incorporated by reference in its entirety. Micro-transfer printing using compound micro-assembly structures and methods can also be used in certain embodiments, for example, as described in U.S. patent application Ser. No. 14/822,868, filed Aug. 10, 2015, entitled Compound Micro-Assembly Strategies and Devices, which is hereby also incorporated by reference in its entirety.

Various embodiments of structures and methods were described herein. Structures and methods were variously described as transferring, printing, or micro-transfer printing micro-devices 20 and LEDs 30. Micro-transfer-printing involves using a transfer device (e.g., an elastomeric stamp, such as a PDMS stamp) to transfer a micro-device 20 or LED 30 using controlled adhesion. For example, an exemplary transfer device can use kinetic or shear-assisted control of adhesion between a transfer device and a micro-device 20 or LED 30. It is contemplated that, in certain embodiments, where a method is described as including micro-transfer-printing a micro-device 20 or LED 30, other analogous embodiments exist using a different transfer method. As used herein, transferring a micro-device 20 or LED 30 can be accomplished using any one or more of a variety of known techniques. For example, in certain embodiments, a pick-and-place method can be used. As another example, in certain embodiments, a flip-chip method can be used (e.g., involving an intermediate, handle or carrier substrate). In methods according to certain embodiments, a vacuum tool or other transfer device is used to transfer a micro-device 20 or LED 30.

As is understood by those skilled in the art, the terms “over” and “under” are relative terms and can be interchanged in reference to different orientations of the layers, elements, and substrates included in various embodiments of the present disclosure. Furthermore, a first layer or first element “on” a second layer or second element, respectively, is a relative orientation of the first layer or first element to the second layer or second element, respectively, that does not preclude additional layers being disposed therebetween. For example, a first layer on a second layer, in some implementations, means a first layer directly on and in contact with a second layer. In other implementations, a first layer on a second layer includes a first layer and a second layer with another layer therebetween (e.g., and in mutual contact). Moreover, the terms “row” and “column” are simply a matter of orientation and can be interchanged.

Throughout the description, where apparatus and systems are described as having, including, or comprising specific elements, or where processes and methods are described as having, including, or comprising specific steps, it is contemplated that, additionally, there are apparatus and systems of the disclosed technology that consist essentially of, or consist of, the recited elements, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously.

Having described certain implementations of embodiments, it will now become apparent to one of skill in the art that other implementations incorporating the concepts of the disclosure may be used. The disclosure has been described in detail with particular reference to certain embodiments thereof, but it will be understood that variations and modifications can be effected within the spirit and scope of the following claims.

### PARTS LIST

A cross section line
10 TFT substrate/display substrate
11 display area
12 thin-film-transistor (TFT) circuit
14 TFT contact pad
16 capacitor/thin-film capacitor
18 adhesive
20 integrated circuit/micro-device
22 micro-circuit
23 integrated-circuit substrate
24 micro-circuit contact pads
26 connection post
27 micro-device electrode
28 electrical via
29 micro-device tether
30 LED/OLED/light emitter
30R red LED
30G green LED
30B blue LED
31 LED substrate
32 anode
34 cathode
36 OLED layers/light-emitting material
37 LED electrode
38 dielectric structures
39 LED tether
40 row-select wire
42 column-data wire
44 thin-film transistor
50 display controller
52 column controller
54 row controller
60 ground
62 Vdd
90 pixel/hybrid-control pixel
92 hybrid-control display
94 cluster/hybrid-control cluster
96 cluster controller
100 provide LED source wafer step
110 provide micro-device source wafer step
120 provide TFT substrate step
130 print LED onto micro-device step
140 print micro-device onto TFT substrate step
150 form LED on micro-device source wafer step
160 print LED onto TFT substrate step
165 form LED on TFT substrate step

1. A hybrid-control pixel, comprising:
a TFT substrate;
a TFT circuit formed on or in the TFT substrate;
a micro-device comprising a micro-circuit and an integrated-circuit substrate, wherein the integrated-circuit substrate is non-native to the TFT substrate and the micro-circuit is electrically connected to the TFT circuit; and
an LED electrically connected to the micro-circuit or to the TFT circuit,
wherein the TFT circuit and the micro-circuit are together operable to control the LED.

2. The hybrid-control pixel of claim 1, comprising three different LEDs disposed on the micro-device.

3. The hybrid-control pixel of claim 2, wherein the three different LEDs comprise a red LED operable to emit red light, a green LED operable to emit green light, and a blue LED operable to emit blue light.

4. The hybrid-control pixel of claim 1, wherein the LED is an OLED.

5. The hybrid-control pixel of claim 4, wherein the OLED is native to the micro-device.

6. The hybrid-control pixel of claim 4, wherein the OLED is native to the TFT substrate.

7. The hybrid-control pixel of claim 4, wherein the OLED (i) is non-native to the micro-device and (ii) is disposed on the micro-device.

8. The hybrid-control pixel of claim 1, wherein the LED is an iLED.

9. The hybrid-control pixel of claim 8, wherein the iLED (i) is non-native to the micro-device and (ii) is disposed on the micro-device.

10. The hybrid-control pixel of claim 1, wherein the LED comprises one or more connection posts electrically connected to the micro-circuit.

11. The hybrid-control pixel of claim 1, wherein the micro-device comprises one or more connection posts electrically connected to the TFT circuit.

12. The hybrid-control pixel of claim 1, wherein the TFT circuit comprises signal selection circuitry.

13. The hybrid-control pixel of claim 1, wherein the micro-circuit comprises LED driving circuitry.

14. The hybrid-control pixel of claim 1, wherein the TFT circuit comprises a thin-film capacitor and the micro-circuit is responsive to the thin-film capacitor.

15. The hybrid-control pixel of claim 1, wherein the micro-circuit is responsive to a voltage provided by the TFT circuit.

16. The hybrid-control pixel of claim 1, wherein the micro-circuit comprises a storage device and the storage device stores a value corresponding to a value provided by the TFT circuit.

17. The hybrid-control pixel of claim 1, wherein (i) the micro-device comprises a micro-device tether, (ii) the LED comprises an LED tether, or both (i) and (ii).

18. The hybrid-control pixel of claim 1, wherein the micro-device is disposed on the TFT substrate.

19. The hybrid-control pixel of claim 1, wherein the TFT circuit comprises circuitry formed in one or more of: amorphous silicon (aSi), low-temperature polycrystalline silicon (LTPS), high-temperature polycrystalline silicon (HTPS), and indium-gallium-zinc-oxide (IGZO).

20. The hybrid-control pixel of claim 1, wherein the TFT circuit comprises (i) circuitry formed in low-temperature polycrystalline silicon (LTPS), (ii) circuitry formed in indium-gallium-zinc-oxide (IGZO), or (iii) both (i) and (ii).

21-56. (canceled)
